(19) United States
(12) Patent Application Publication
(10) Pub. No.: US 2026/0136627 A1
(43) Pub. Date: May 14, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Yung-Ting CHANG, New Taipei (TW); Jui-Lin CHEN, Taipei (TW); Chen-Ming LEE, Taoyuan (TW)

(21) Appl. No.: 19/063,454

(22) Filed: Feb. 26, 2025

Related U.S. Application Data
(60) Provisional application No. 63/719,166, filed on Nov. 12, 2024.

(51) Int. Cl. H10D 64/23; H10D 84/01

(52) U.S. Cl. CPC H10D 64/254; H10D 84/013; H10D 84/0149

(57) ABSTRACT

Embodiments of the present disclosure provide semiconductor device structures and methods of forming the same. The semiconductor device structure includes a first source/drain region, a second source/drain region disposed adjacent the first source/drain region, and a contact etch stop layer disposed over the first source/drain region. A top surface of the first source/drain region is covered by the contact etch stop layer. The structure further includes a first conductive feature disposed below the first and second source/drain regions, and the first conductive feature is electrically connected to the first and second source/drain regions.

### CROSS-REFERENCE TO RELATED APPLICATIONS

This application claims priority to U.S. Provisional Application Ser. No. 63/719,166 filed on Nov. 12, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, 10, 11, and 12 are perspective views of various stages of manufacturing a semiconductor device structure, in accordance with some embodiments.

FIGS. 13, 14, 15, 16, and 17 are cross-sectional side views of the semiconductor device structure at various manufacturing stages, in accordance with some embodiments.

FIG. 18 is a top view of the semiconductor device structure, in accordance with some embodiments.

FIGS. 19A and 19B are cross-sectional side views of the semiconductor device structure taken along the line A-A of FIG. 18, in accordance with some embodiments.

FIG. 20 is a cross-sectional side view of the semiconductor device structure taken along the line B-B of FIG. 18, in accordance with some embodiments.

FIGS. 21A and 21B are cross-sectional side views of the semiconductor device structure taken along the line C-C of FIG. 18, in accordance with some embodiments.

FIG. 22 is a top view of the semiconductor device structure, in accordance with alternative embodiments.

FIGS. 23A and 23B are cross-sectional side views of the semiconductor device structure taken along the line D-D of FIG. 22, in accordance with some embodiments.

FIGS. 24, 25, 26, and 27 are top views of the semiconductor device structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

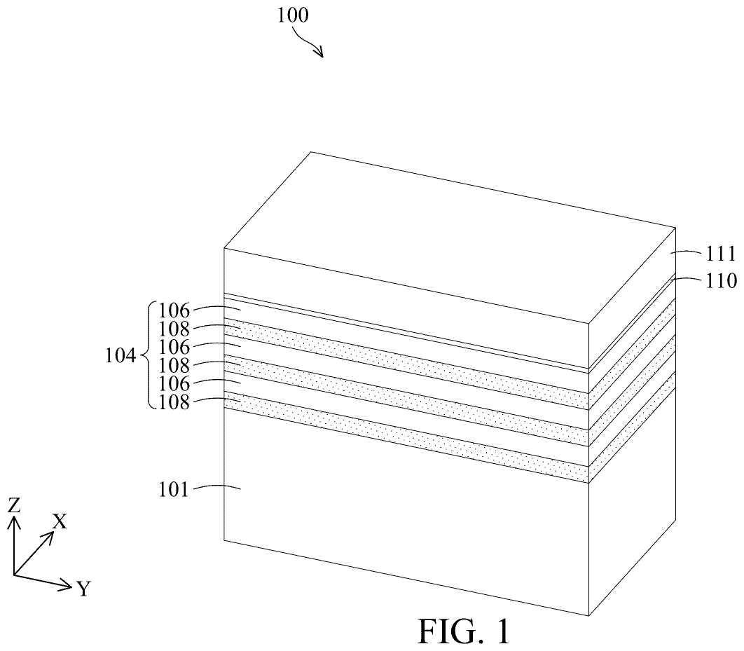

FIGS. 1 to 17 show exemplary processes for manufacturing a semiconductor device structure 100 according to embodiments of the present disclosure. It is understood that additional operations can be provided before, during, and after processes shown by FIGS. 1 to 17, and some of the operations described below can be replaced or eliminated, for additional embodiments of the method. The order of the operations/processes is not limiting and may be interchangeable.

FIGS. 1 to 12 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm, such as from about 3 nm to about 10 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

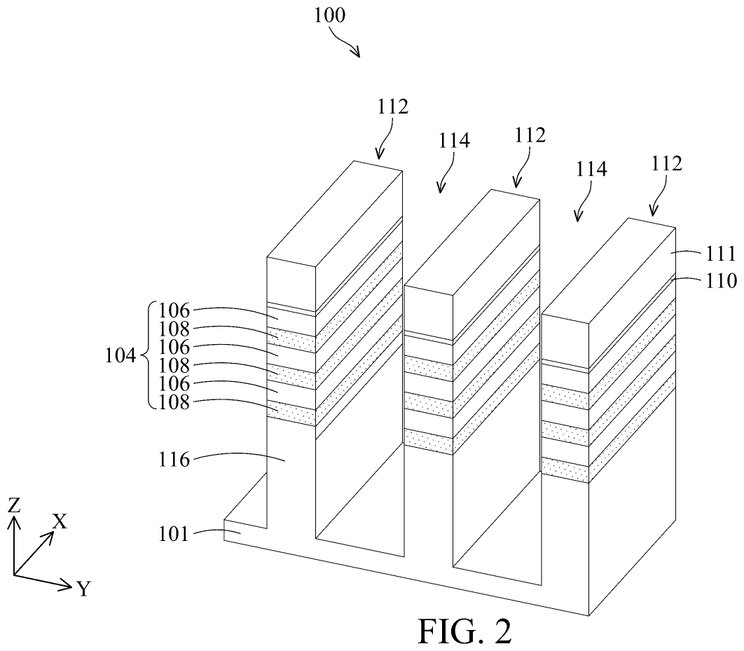

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

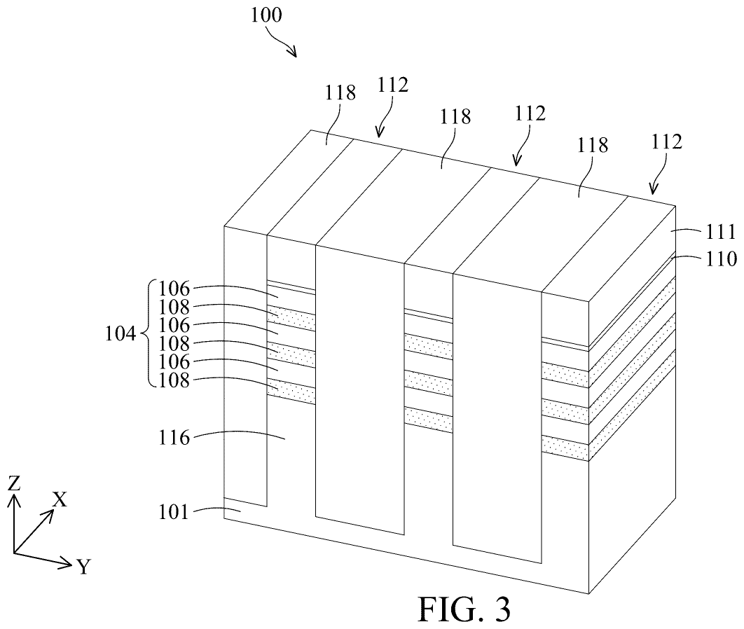

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

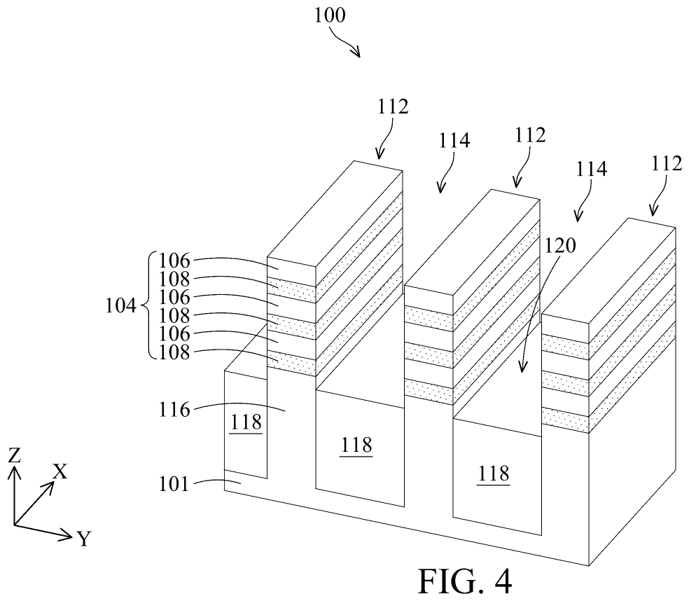

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101. In some embodiments, the isolation regions 120 are the STI. In some embodiments, the oxide layer 110 and the nitride layer 111 are also removed during the recessing of the insulating material 118.

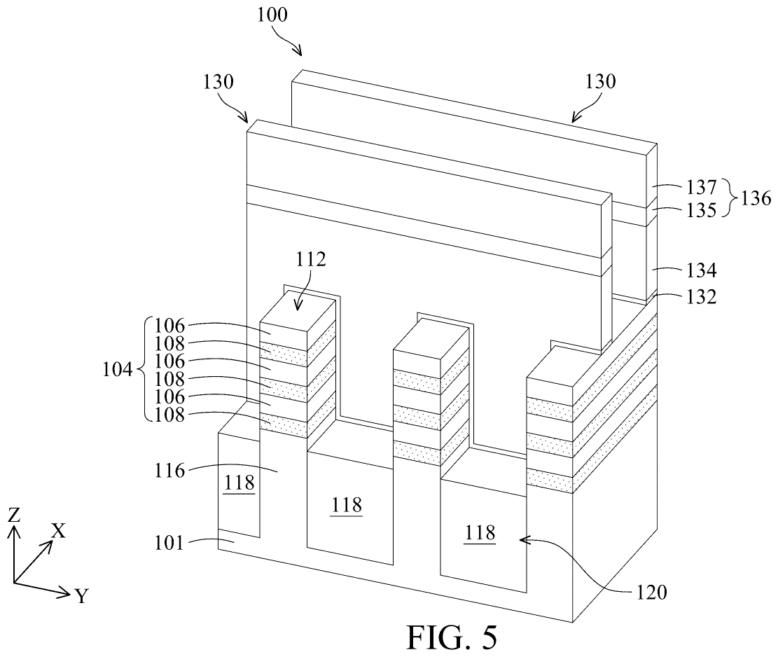

In FIG. 5, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100.

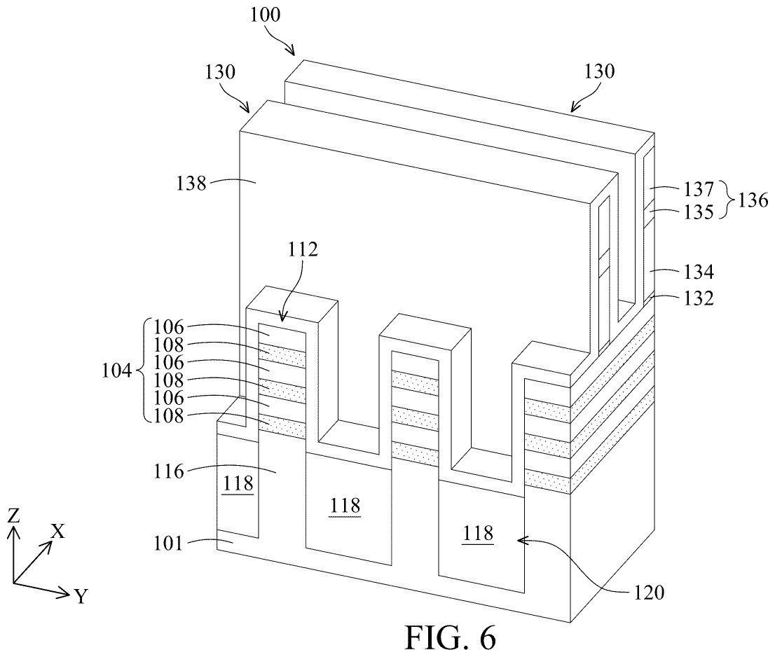

In FIG. 6, a gate spacer layer 138 is formed to cover the sacrificial gate structures 130, the second portions of the fin structures 112, and the second portions of the isolation regions 120. The gate spacer layer 138 may include one or more layers of dielectric material, such as silicon oxide, silicon nitride, silicon carbide, silicon oxynitride, SiCN, silicon oxycarbide, SiOCN, and/or combinations thereof. In some embodiments, the gate spacer layer 138 is formed by a conformal process, such as an atomic layer deposition (ALD) process.

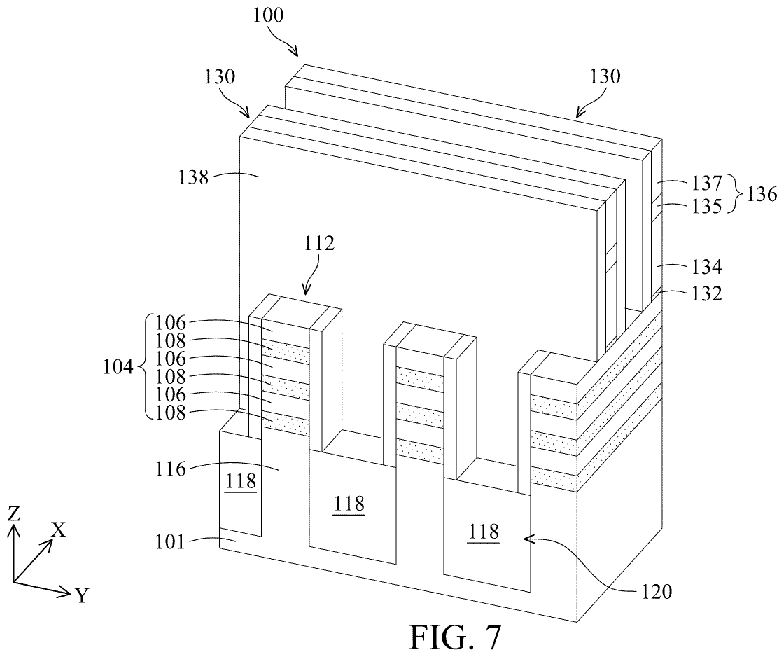

In FIG. 7, an anisotropic etch process is performed to remove horizontal portions of the gate spacer layer 138. The anisotropic etch process may be a selective etch process that does not substantially affect the nitride layer 137, the first semiconductor layer 106, and the isolation region 120. As a result, the second portions of the fin structures 112 are exposed.

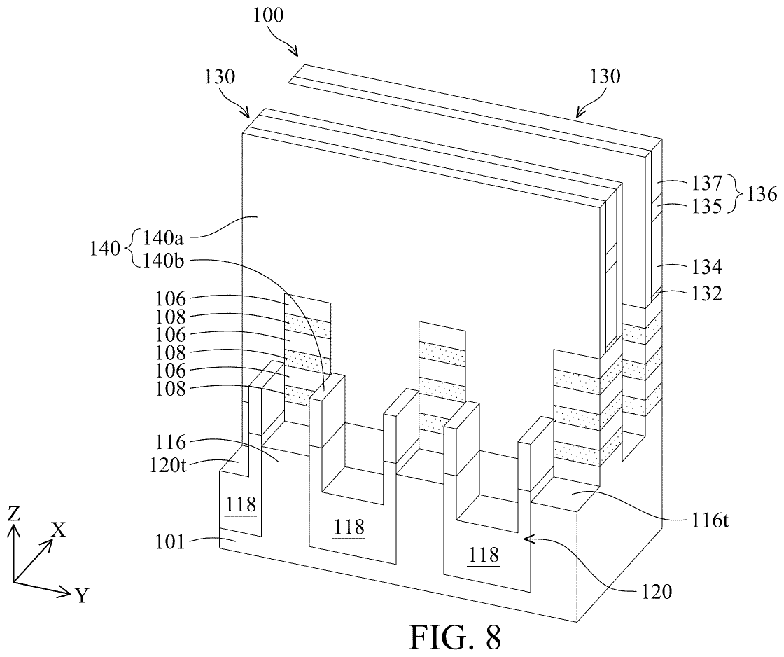

In FIG. 8, one or more etch processes are performed to recess the exposed second portions of the fin structures 112 not covered by the sacrificial gate structures 130 (and the portions of the gate spacer layer 138 formed on sidewalls of the sacrificial gate structures 130) and to remove portions of the gate spacer layer 138. The portions of the gate spacer layer 138 formed on sidewalls of the mask layer 136 may be also recessed. The one or more etch processes may include a dry etch, such as a RIE, NBE, or the like, and/or a wet etch, such as using tetramethyalammonium hydroxide (TMAH), ammonium hydroxide (NH₄OH). The one or more etch processes form gate spacers 140 including a first portion 140a formed on sidewalls of the sacrificial gate electrode layer 134 and second portions 140b formed on the second portions of the isolation regions 120. In some embodiments, the one or more etch processes also remove portions of the second portions of the isolation regions 120, as shown in FIG. 8. As a result, the top surface 120t of the second portion of the isolation region 120 is located at a level substantially below the top surface 116t of the substrate portion 116.

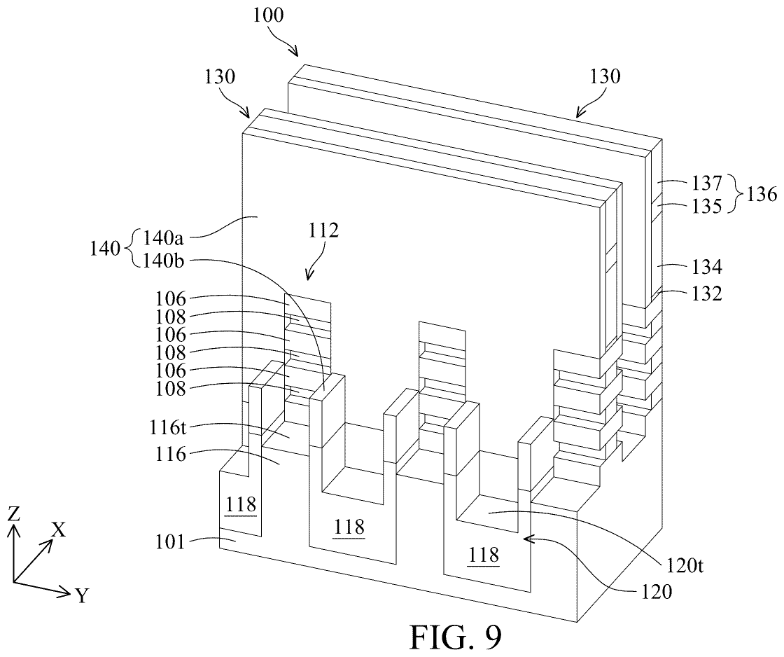

As shown in FIG. 9, edge portions of each second semiconductor layer 108 of the stack of semiconductor layers 104 are removed horizontally along the X direction. The removal of the edge portions of the second semiconductor layers 108 forms cavities. In some embodiments, the edge portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

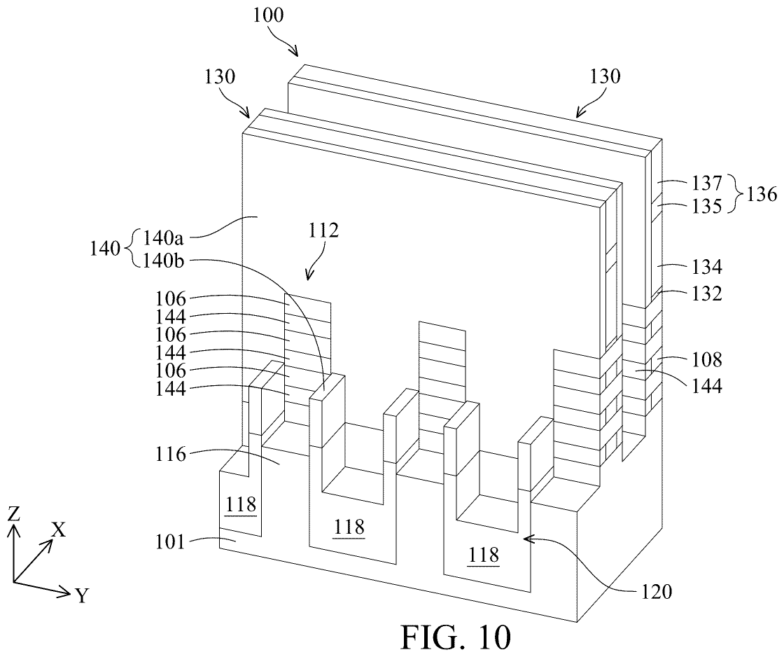

After removing edge portions of each second semiconductor layers 108, a dielectric layer is deposited in the cavities to form dielectric spacers 144, as shown in FIG. 10. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

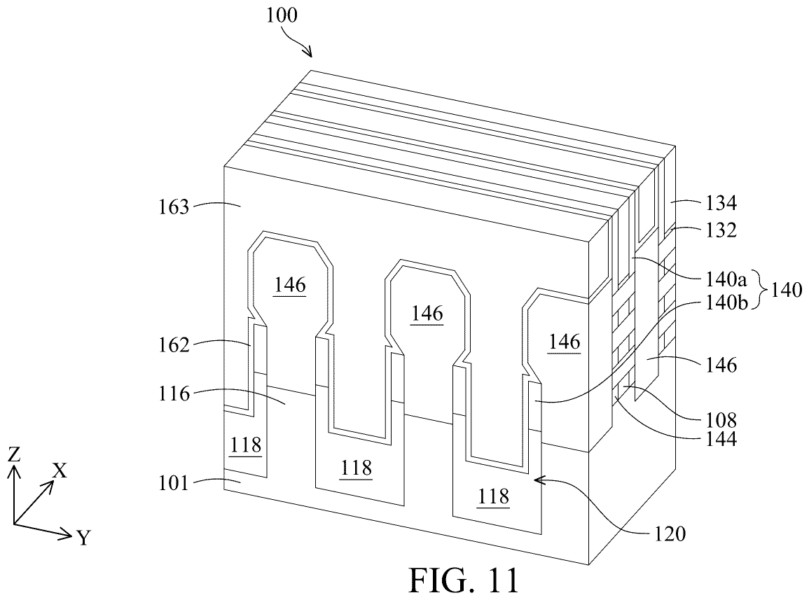

As shown in FIG. 11, source/drain (S/D) regions 146 are formed from the substrate portions 116. In some embodiments, the S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. In some embodiments, the S/D regions 146 are n-type S/D epitaxial features and may be made of one or more layers of Si, SiP, SiC and SiCP for n-channel FETs. In some embodiments, the S/D regions 146 are p-type epitaxial features and may be made of one or more layers of Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. In some embodiments, a thickness of the S/D region 146 along the Z direction is different from a width of the S/D region 146 along the Y direction.

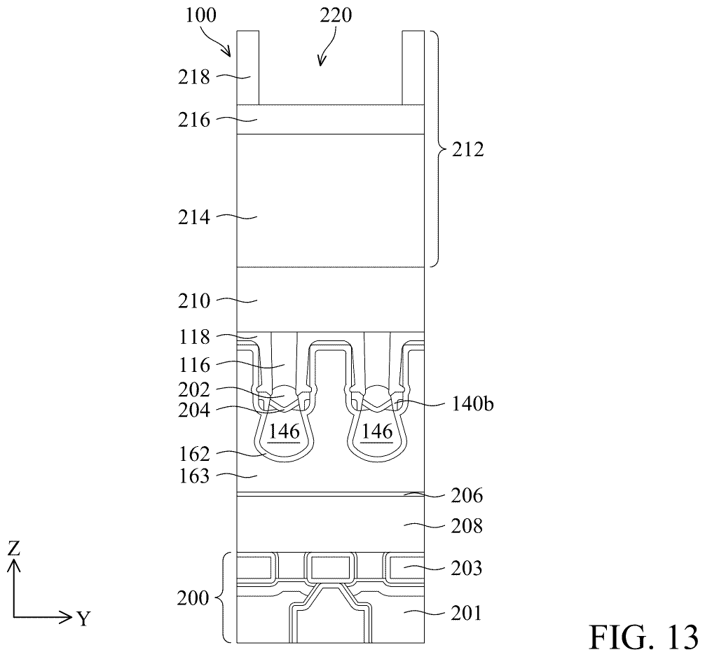

In some embodiments, a semiconductor layer 202 (FIG. 13) is first formed on the substrate portions 116, a dielectric layer 204 (FIG. 13) is formed on the semiconductor layer 202, and the S/D regions 146 are formed from the first semiconductor layers 106. The semiconductor layer 202 may be undoped silicon, and the dielectric layer 204 may be a nitride layer, such as a SiN layer.

After forming the S/D regions 146, a contact etch stop layer (CESL) 162 is conformally formed on the exposed surfaces of the semiconductor device structure 100. The CESL 162 covers the sidewalls of the first portion 140a of the gate spacers 140 and is disposed on the second portion 140b of the gate spacers 140 and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

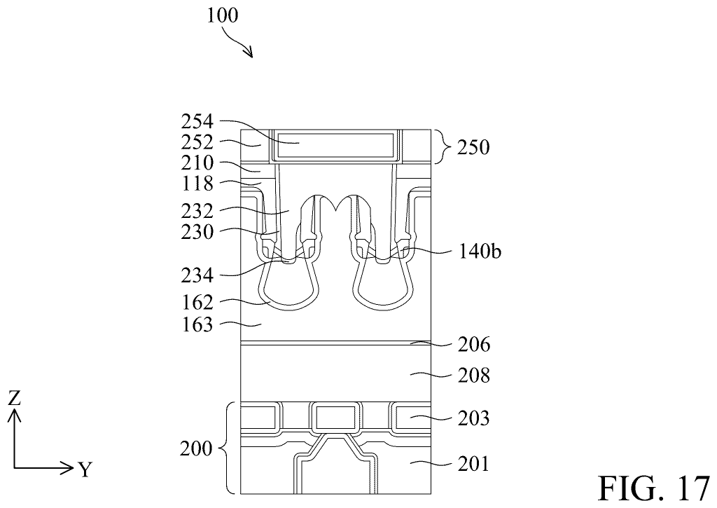

A planarization process is performed to expose the sacrificial gate electrode layer 134, as shown in FIG. 17. The planarization process may be any suitable process, such as a CMP process. The planarization process removes portions of the ILD layer 163 and the CESL 162 disposed on the sacrificial gate stacks 130. The planarization process may also remove the mask structure 136.

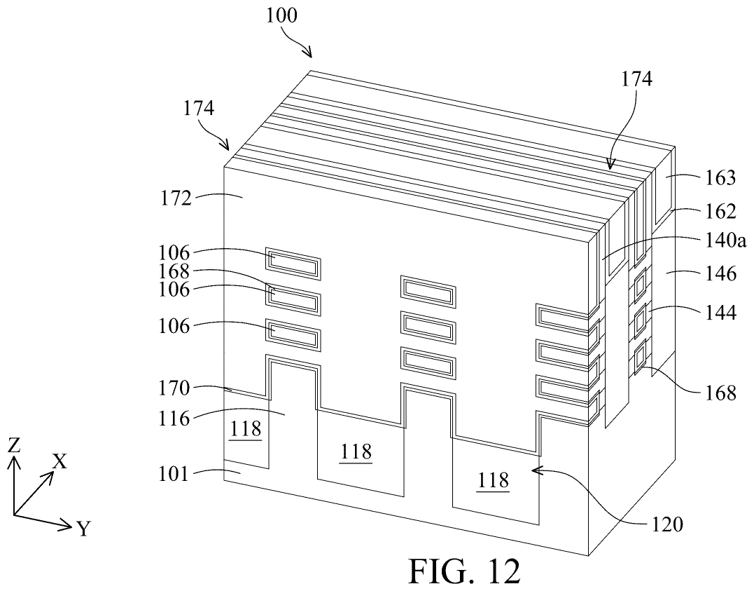

As shown in FIG. 12, the sacrificial gate electrode layer 134, the sacrificial gate dielectric layer 132, and the second semiconductor layers 108 are removed to expose portions of the first semiconductor layers 106, and a gate dielectric layer 170 and a gate electrode layer 172 are formed to surround the exposed portions of the first semiconductor layers 106. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 140, the ILD layer 163, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 140, the ILD layer 163, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

As shown in FIG. 12, the gate dielectric layer 170 and the gate electrode layer 172 may be collectively referred to as a gate structure 174. In some embodiments, an interfacial layer (IL) 168 is formed between the gate dielectric layer 170 and the exposed surfaces of the first semiconductor layers 106. The IL 168 may include an oxide, such as silicon oxide, and may be formed as a result of a clean process. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed.

As shown in FIG. 13, another etch stop layer 206 is deposited on the ILD layer 163, and another ILD layer 208 is deposited on the etch stop layer 206. The etch stop layer 206 may include the same material as the CESL 162, and the ILD layer 208 may include the same material as the ILD layer 163. In some embodiments, a thickness of the ILD layer 163 is greater than a thickness of the ILD layer 208. In some embodiments, openings (not shown) are formed in the ILD layer 208, the etch stop layer 206, the ILD layer 163, and the CESL 162 to expose the S/D regions 146, and conductive features (not shown) are formed in the openings and are electrically connected to the S/D regions 146 via silicide layers (not shown). The conductive features provide power or signal to the S/D regions 146 from the frontside of the semiconductor device structure 100. In some embodiments, power to certain S/D regions 146 is provided from the backside of the semiconductor device structure 100, and the conductive features are not formed over the S/D regions 146 on the frontside of the semiconductor device structure 100. In some embodiments, the conductive features are formed over some S/D regions 146, and other S/D regions 146 are without the frontside conductive features. Conductive features (not shown) may be formed in the ILD layer 208 and the etch stop layer 206 to electrically connect with the gate structures 174.

Next, an interconnect structure 200 is formed over the ILD layer 208. The interconnect structure 200 includes a plurality of intermetal dielectric (IMD) layers 201 and conductive features 203, such as conductive lines and vias, formed in the IMD layers 201. The interconnect structure 200 may further include passivation layers, adhesion layers, and/or other layers formed on the frontside of the semiconductor device structure 100. Next, a carrier substrate (not shown) is attached to the semiconductor device structure 100 on the frontside, and the semiconductor device structure 100 is flipped over for backside processing, as shown in FIG. 13. In some embodiments, the substrate 101 is thinned down until the insulating material 118 is shown, as shown in FIG. 13. The thinning process may include a mechanical grinding process and/or a chemical thinning process. A substantial amount of substrate material may be first removed from the substrate 101 during a mechanical grinding process. Afterwards, a chemical thinning process may apply an etching chemical to the backside of the substrate 101 to further thin down the substrate 101.

As shown in FIG. 13, a hardmask layer 210 is deposited over the backside of the semiconductor device structure 100 and a tri-layer resist layer 212 is formed over the hardmask layer 210. The hardmask layer 210 may include an oxide (e.g., SiO₂), a nitride (e.g., SiN), an oxy-nitride (e.g., SiOₓN_{y}), or the like. In further embodiments, the hardmask layer 210 is SiO₂. In yet further embodiments, the hardmask layer 210 is a high-temperature oxide (HTO) (e.g., SiO₂ formed by a high-temperature deposition/growth process). In some embodiments, a process for forming the hardmask layer 210 includes depositing a dielectric material on the backside of the semiconductor device structure 100 by, for example, CVD, PVD, ALD, sputtering, some other deposition process, or a combination thereof.

The tri-layer resist layer 212 includes a bottom layer 214 over the hardmask layer 210, a middle layer 216 over the bottom layer 214, and an upper layer 218 over the middle layer 216. The bottom layer 214 may be a bottom anti-reflective coating (BARC). The bottom layer 214 may include organic materials. The middle layer 216 may be formed from or include an inorganic material, which may be a nitride (such as silicon nitride), an oxynitride (such as silicon oxynitride), an oxide (such as silicon oxide), or the like. The upper layer 218 is a photosensitive material. In some embodiments, the resist layer formed over the hardmask layer 210 may be another type of photoresist, such as a single-layer photoresist, a bi-layer photoresist, or the like. The upper layer 218 is patterned using any suitable photolithography technique to form trench opening 220 therein.

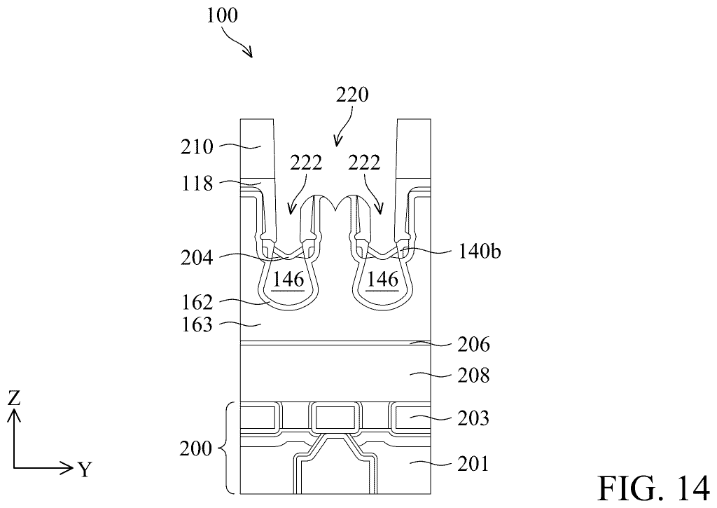

As shown in FIG. 14, the trench opening 652 is extended to the hardmask layer 210 and selectively etches the substate portions 116 to form backside via holes 222. The pattern of the upper layer 218 is transferred to the middle layer 216 using a suitable etching process. Next, a suitable etching process is performed to transfer the pattern of the middle layer 216 to the bottom layer 214, thereby extending the trench opening 220 through the bottom layer 214. Further, the pattern of the bottom layer 214 is transferred to the hardmask layer 216 using a suitable etching process. In an embodiment, the etching process used to etch the bottom layer 214 is continued to etch the hardmask layer 210. During the etching process, the upper layer 218, middle layer 216, and bottom layer 214 may be consumed. In some embodiments, an ashing process may be performed to remove remaining residue of the bottom layer 214. After the patten of the hardmask layer 210 exposes the backside of the semiconductor device structure 100, an etching process that is tuned to be selective to the materials of the substrate portions 116 is performed. In the present embodiment, the etching process also etches the semiconductor layer 202. The dielectric layer 204 may function as an etch stop layer to protect the S/D regions 146 from being etched. The etching process can be dry etching, wet etching, reactive ion etching, or other suitable etching methods.

In some embodiments, the etching process that removes the substrate portions 116 also removes a horizontal portion of the insulating material 118 located between adjacent substrate portions 116, as shown in FIG. 14. In some embodiments, the portion of the CESL 162 and the portion of the ILD layer 163 located under the horizontal portion of the insulating material 118 may be also removed, as shown in FIG. 14. In some embodiments, the opening in the ILD layer 163 has a decreasing width along the Y direction, as shown in FIG. 14. In some embodiments, the opening in the ILD layer 163 has a substantially constant width along the Y direction.

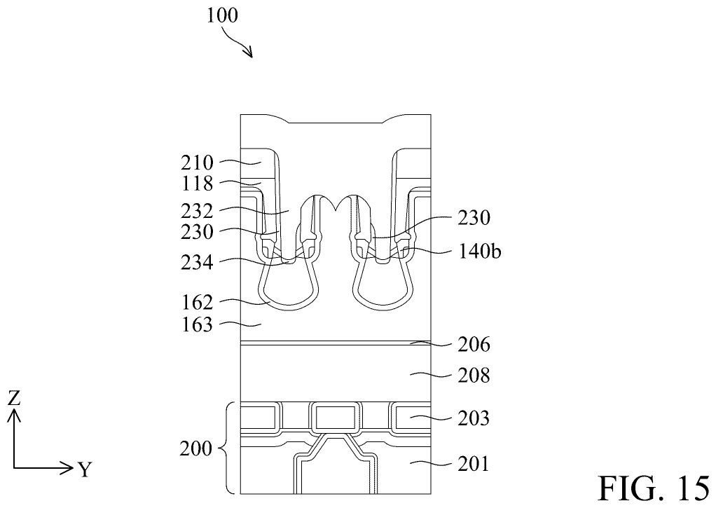

As shown in FIG. 15, a dielectric liner 230 is formed on sidewalls of the trench opening 220 (including backside via holes 222). The dielectric liner 230 further protects the gate structure 174 from metal element diffusion when conductive features are subsequently formed in the trench opening 220. In some embodiments, the dielectric liner 230 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, combinations thereof, or other suitable material(s). The dielectric liner 230 may be first deposited using ALD, CVD, or other suitable methods. Subsequently, an anisotropic etching process is performed to remove the horizontal portions of the dielectric liner 230. In the illustrated embodiment, as a result of the anisotropic etching process, portions of the dielectric liner 230 remain on sidewalls of the insulating material 118. The dielectric liner 230 may also be in contact with the second portion 140b of the gate spacer 140. After the anisotropic etching process, the dielectric layer 204 as an etch stop layer is exposed in the backside via holes 222. Subsequently, an etching process is applied to remove the exposed portion of the dielectric layer 204. The etching process can be dry etching, wet etching, reactive ion etching, or other etching methods. After the etching process, the backside via holes 222 exposes bottom surface of the S/D regions 146 from the backside. A portion of the dielectric layer 204 may remain between the S/D region 146 and the dielectric liner 230.

As shown in FIG. 15, a conductive feature 232 is formed in the trench opening 220 and the backside via holes 222. The conductive feature 232 may include any suitable electrically conductive material, such as tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In some embodiments, a silicide layer 234 is formed between the conductive feature 232 and the S/D region 146. The silicide layer 234 reduces contact resistance between the S/D regions 146 and the conductive feature 232. The silicide layers 234 may be formed by depositing one or more metals into the backside via holes 222, performing an annealing process to cause reaction between the one or more metals and the S/D regions 146 to produce the silicide layers 234, and removing un-reacted portions of the one or more metals, leaving the silicide layers 234 in the backside via holes 222. The one or more metals may include titanium (Ti), tantalum (Ta), tungsten (W), nickel (Ni), platinum (Pt), ytterbium (Yb), iridium (Jr), erbium (Er), cobalt (Co), or a combination thereof (e.g., an alloy of two or more metals) and may be deposited using CVD, PVD, ALD, or other suitable methods. The silicide layer 234 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. Alternatively, the conductive feature 232 may directly contact the two S/D regions 146.

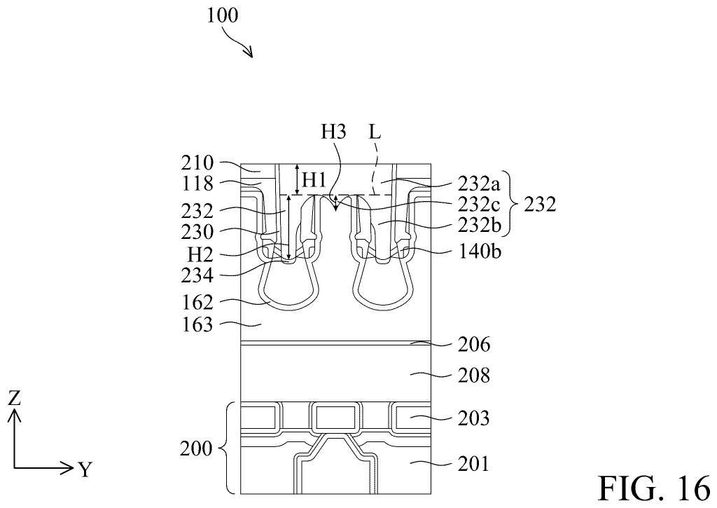

As shown in FIG. 16, a planarization process, such as a CMP process, is performed to remove the portion of the conductive feature 232 formed on the hardmask layer 210. In some embodiments, the top surface of the conductive feature 232 and the top surface of the hardmask layer 210 are substantially coplanar. The conductive feature 232 has a first portion 232a and second portions 232b extending from edges of the first portion 232a, as shown in FIG. 16. The conductive feature 232 may further include a third portion 232c extending from the center of the first portion 232a. The conductive feature 232 is monolithic, and the first, second, and third portions 232a, 232b, 232c are defined by an imaginary line L, as shown in FIG. 16. The first portion 232a has a height H1, the second portion 232b has a height H2, and the third portion 232c has a height H3. The imaginary line L may be drawn at a location so the height H1 is constant. In some embodiments, the height H1 is less than the height H2, and the height H3 is less than the height H1, as shown in FIG. 16. In some embodiments, the height H1 is greater than the height H2. The third portion 232c provides a larger volume of the conductive feature 232. As a result, electrical resistance is reduced.

As shown in FIG. 17, backside interconnect structure 250 is formed on the hardmask layer 210 and the conductive feature 232. The backside interconnect structure 250 includes one or more IMD layers 252 and conductive features 254 formed in the IMD layers 252.

In some embodiments, the semiconductor device structure 100 includes logic devices. For logic devices, the voltage applied to the source region and the drain region is high, and the voltage applied to the gate is low. If the conductive feature for the S/D region 146 of the logic device is located at the frontside of the semiconductor device structure 100 adjacent the gate structure 174, there would be a high capacitance (Cgd) between the conductive feature for the S/D region 146 and the adjacent gate structure 174. In order to reduce the Cgd, the conductive feature 232 for the S/D region 146 is moved to the backside of the semiconductor device structure 100, as shown in FIG. 17. In some embodiments, the conductive feature 232 is electrically connected to two source regions 146, as shown in FIG. 17. The larger conductive feature 232 reduces electrical resistance.

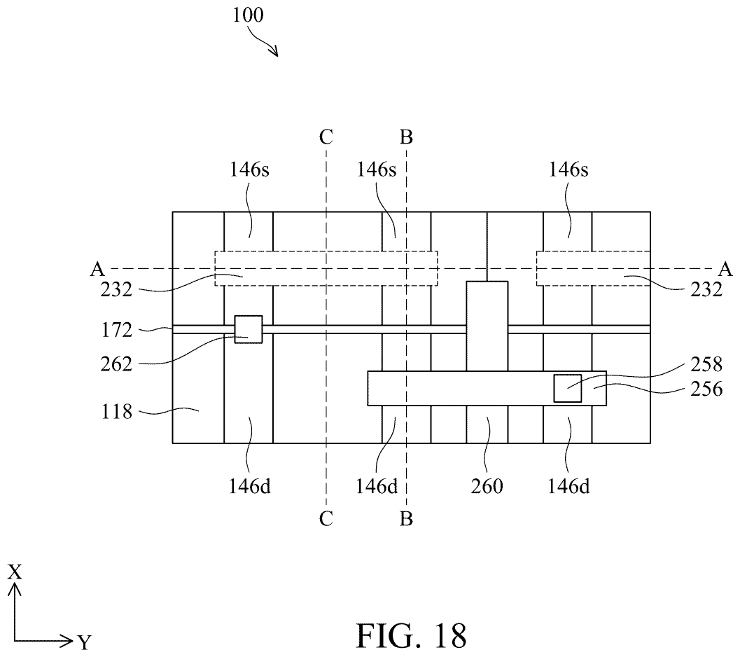

FIG. 18 is a top view of the semiconductor device structure 100, in accordance with some embodiments. As shown in FIG. 18, a gate electrode layer 172 is extending along the Y direction, source regions 146s are disposed on one side of the gate electrode layer 172, while drain regions 146d are disposed on the other side of the gate electrode layer 172. The gate electrode layer 172 may be separated by a dielectric layer 260 by a cut metal gate (CMG) process. A conductive feature 262 may be disposed on the gate electrode layer 172, such as through the ILD layer 208 and the etch stop layer 206 (FIG. 17), to function as a gate contact. The conductive feature 232 is electrically connected to two source regions 146s. In some embodiments, a conductive feature 256 for a corresponding drain region 146d of one of the two source regions 146s is formed on the frontside of the semiconductor device structure 100. In some embodiments, the conductive feature 256 extends across two drain regions 146d and are electrically connected to the two drain regions 146d, as shown in FIG. 18. In some embodiments, the width of the conductive feature 232 along the X direction is substantially the same as the width of the conductive feature 256 along the X direction, as shown in FIG. 18. A conductive feature 258 may be formed on the conductive feature 256.

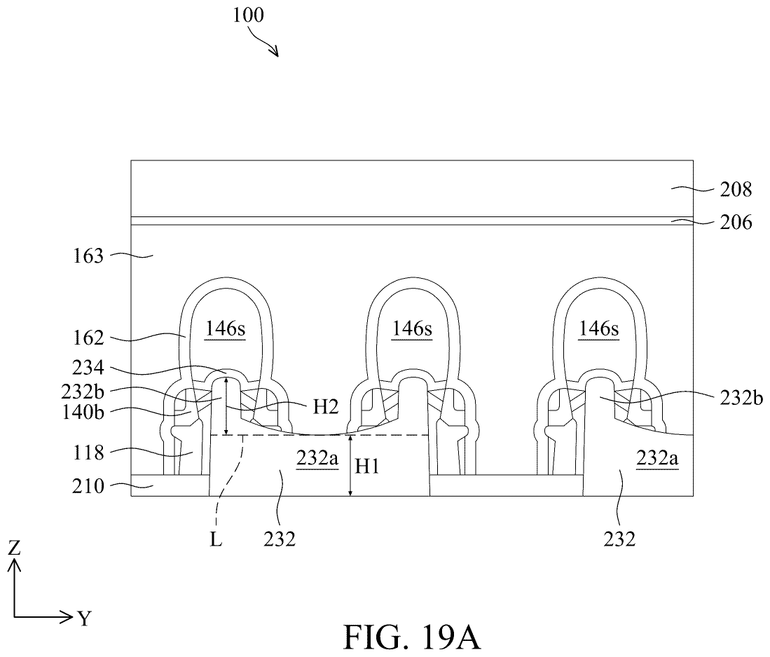

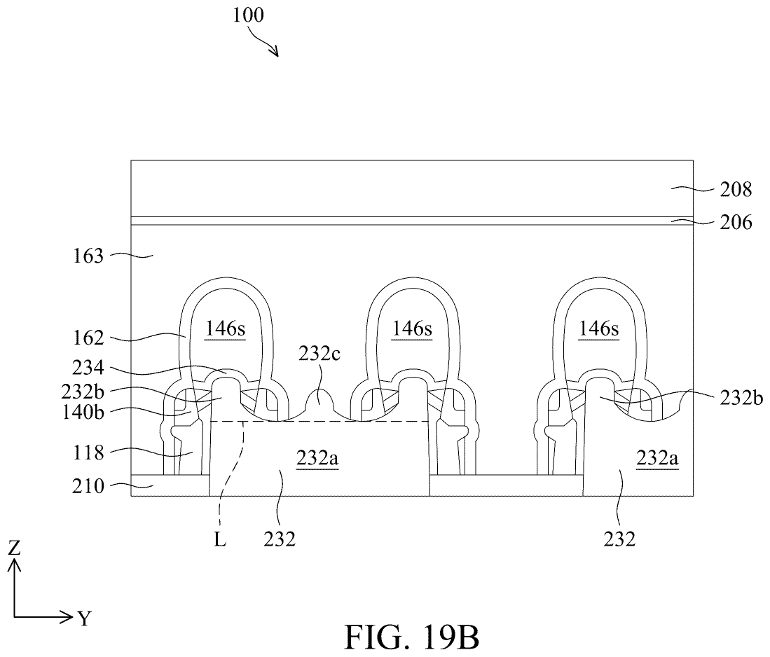

FIGS. 19A and 19B are cross-sectional side views of the semiconductor device structure 100 taken along the line A-A of FIG. 18, in accordance with some embodiments. In some embodiments, as shown in FIG. 19A, the conductive feature 232 includes the first portion 232a having the height H1 and the second portion 232b having the height H2 less than the height H1. With the first portion 232a having the greater height H1, the volume of the conductive feature 232 is increased compared to the conductive feature 232 shown in FIG. 16. As a result, electrical resistance of the conductive feature 232 is reduced. The height H1 may be controlled by controlling the etch process to form the trench opening 220 and backside via holes 222. If the etch chemistry of the etch process is less selective, more ILD layer 163 may be removed, and the height H1 is increased. If the etch chemistry is more selective, less ILD layer 163 may be removed, and the height H1 is decreased.

In some embodiments, as shown in FIG. 19B, the conductive feature 232 includes the third portion 232c. With the third portion 232c, the electrical resistance of the conductive feature 232 is further reduced.

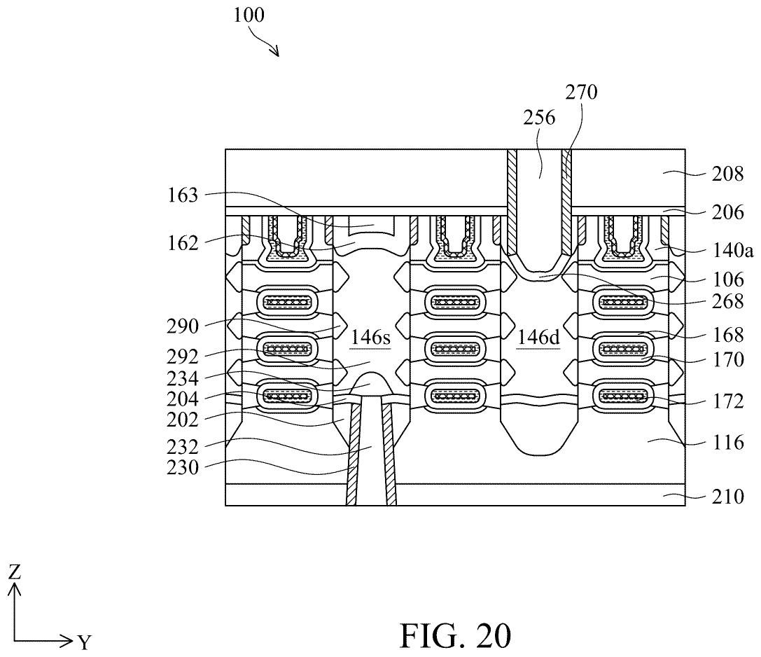

FIG. 20 is a cross-sectional side view of the semiconductor device structure 100 taken along the line B-B of FIG. 18, in accordance with some embodiments. As shown in FIG. 20, in some embodiments, the source region 146s of a transistor is electrically connected to the conductive feature 232 located below the source region 146s, and the drain region 146d of the transistor is electrically connected to the conductive feature 256 located over the drain region 146d. By placing the conductive features 232, 256 on opposite sides of the semiconductor device structure 100, the Cgd is reduced. In some embodiments, the drain region 146d is electrically connected to the conductive feature 158 by a silicide layer 268. The silicide layer 268 may include the same material as the silicide layer 234 and may be formed by the same process as the silicide layer 234. In some embodiments, a dielectric liner 270 is disposed along the sidewall of the conductive feature 256. The dielectric liner 270 may include the same material as the dielectric liner 230 and may be formed by the same process as the dielectric liner 230.

In some embodiments, each of the source region 146s and drain region 146d includes a first epitaxial layer 290 and a second epitaxial layer 292. In some embodiments, both the first and second epitaxial layers 290, 292 are doped with a dopant, such as p-type dopant or n-type dopant. The dopant concentration in the first epitaxial layer 290 is different from the dopant concentration in the second epitaxial layer 292.

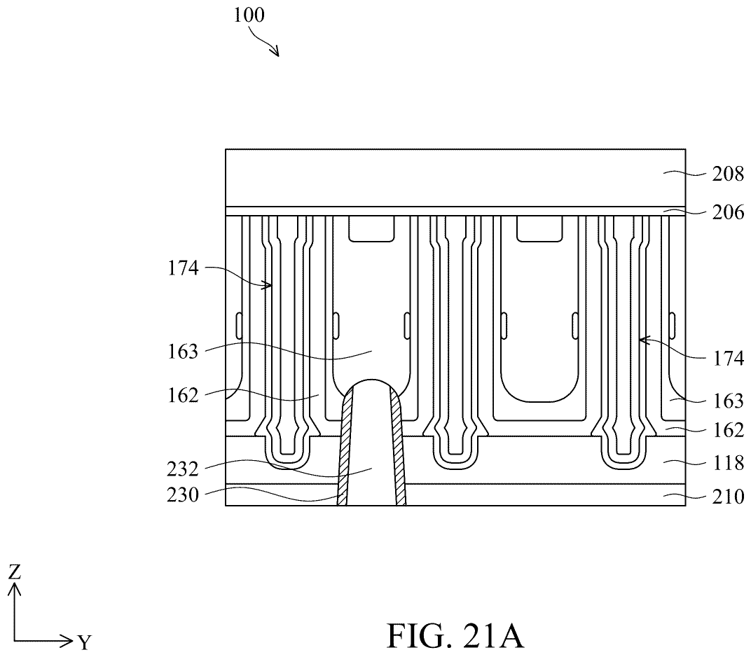

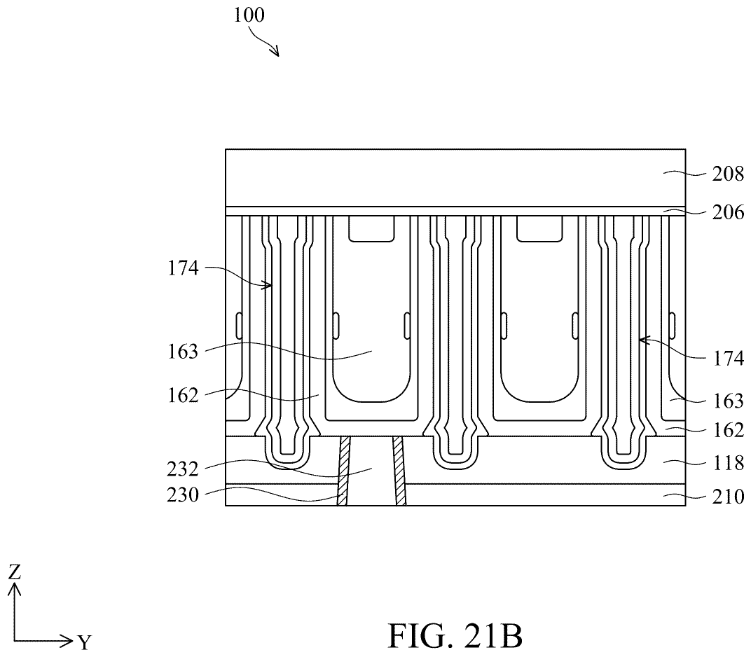

FIGS. 21A and 21B are cross-sectional side views of the semiconductor device structure 100 taken along the line C-C of FIG. 18, in accordance with some embodiments. As shown in FIG. 21A, in some embodiments, the conductive feature 232 may extend through the hardmask layer 210, the insulating material 118, the CESL 162 and into the ILD layer 163. In some embodiments, as shown in FIG. 21B, the conductive feature 232 does not extend into the CESL 162. The CESL 162 may function as an etch stop layer when forming the trench opening 220 and backside via holes 222. The conductive feature 232 extending through or stops at the CESL 162 may be controlled by controlling the etch process to form the trench opening 220 and the backside via opening 222. By using an etch chemistry that does not affect the CESL 162, the CESL 162 can function as an etch stop layer. On the other hand, by using an etch chemistry that also etches the CESL 162, the trench opening 220 also extends through the CESL 162 and into the ILD layer 163.

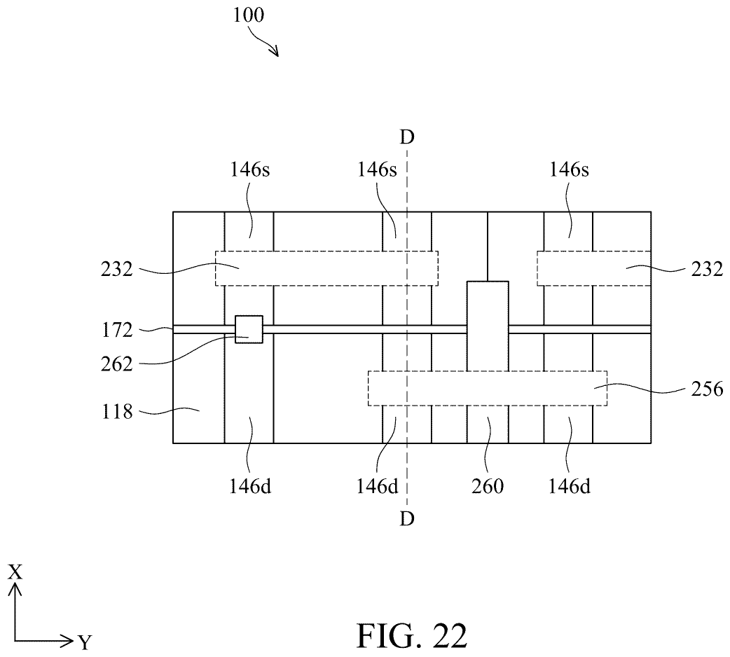

FIG. 22 is a top view of the semiconductor device structure 100, in accordance with alternative embodiments. In some embodiments, the conductive feature 256 is also located on the backside of the semiconductor device structure 100, as shown in FIG. 22. As described above, the voltage applied to the source region 146s and the drain region 146d of a logic device is relatively high compared to the voltage applied to the gate electrode layer 172. Thus, by placing the conductive features 232, 256 for the source region 146s and the drain region 146d, respectively, on the backside of the semiconductor device structure 100, the conductive features 232, 256 and the gate electrode layer 172 have smaller overlapping areas, and the Cgd is further reduced.

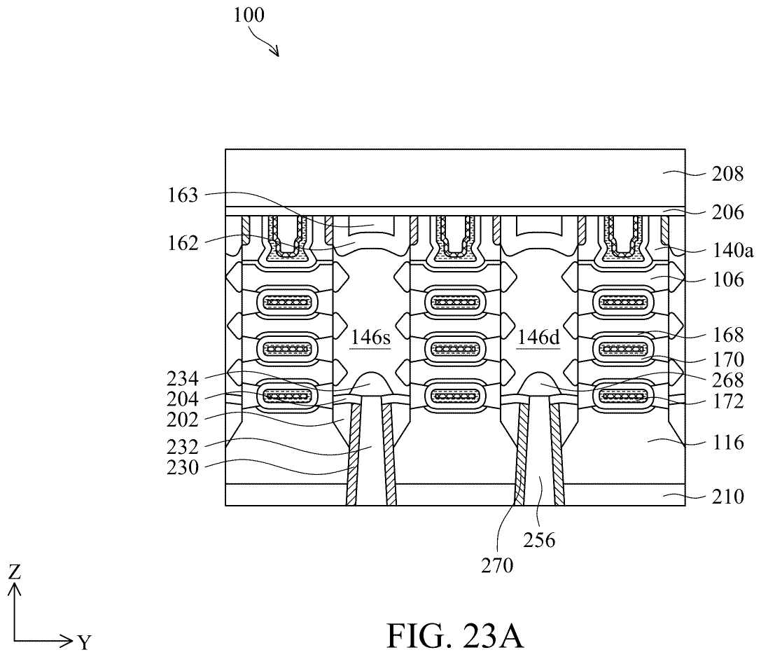

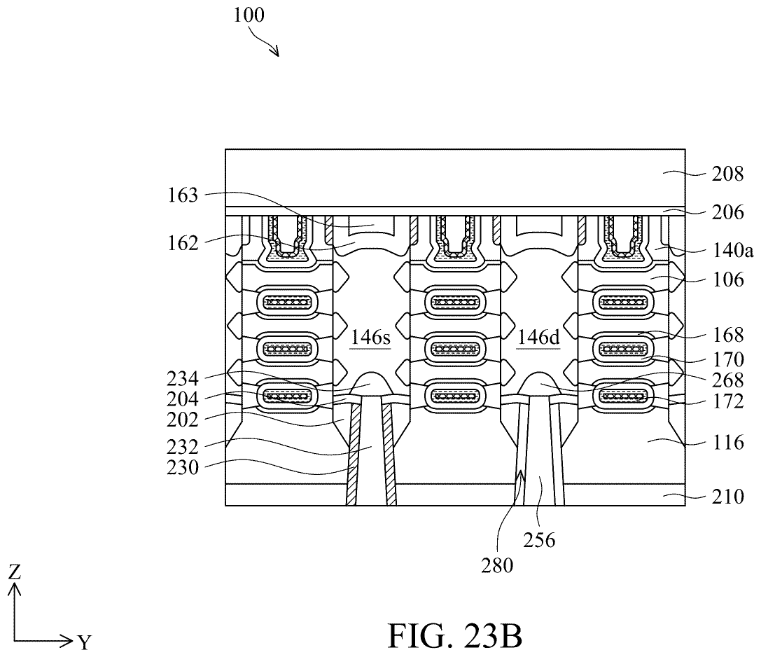

FIGS. 23A and 23B are cross-sectional side views of the semiconductor device structure 100 taken along the line D-D of FIG. 22, in accordance with some embodiments. In some embodiments, as shown in FIG. 23A, the conductive feature 256 extends through the hardmask layer 210, the substrate portion 116, the semiconductor layer 202, and the dielectric layer 204 and is in electrical connection with the drain region 146d via the silicide layer 268. The dielectric liner 270 is located along the sidewall of the conductive feature 256, as shown in FIG. 23A.

In some embodiments, as shown in FIG. 23B, the dielectric liner 270 is replaced with an air gap 280 in order to further reduce capacitance. The air gap 280 may be formed by first forming a liner on the sidewalls of the substrate 116 and the hardmask layer 210 in an opening prior to forming the conductive feature 256 into the opening. The liner may include a material different from those of the hardmask layer 210 and the conductive feature 256. In some embodiments, the liner is made of amorphous silicon. Next, the conductive feature 256 is formed in the opening and adjacent the liner. The liner is then removed to form the air gap 280. The liner may be removed by a selective etch process that does not substantially affect the hardmask layer 210 and the conductive feature 256. The air gap 280 may be formed around the conductive feature 256 and/or the conductive feature 232.

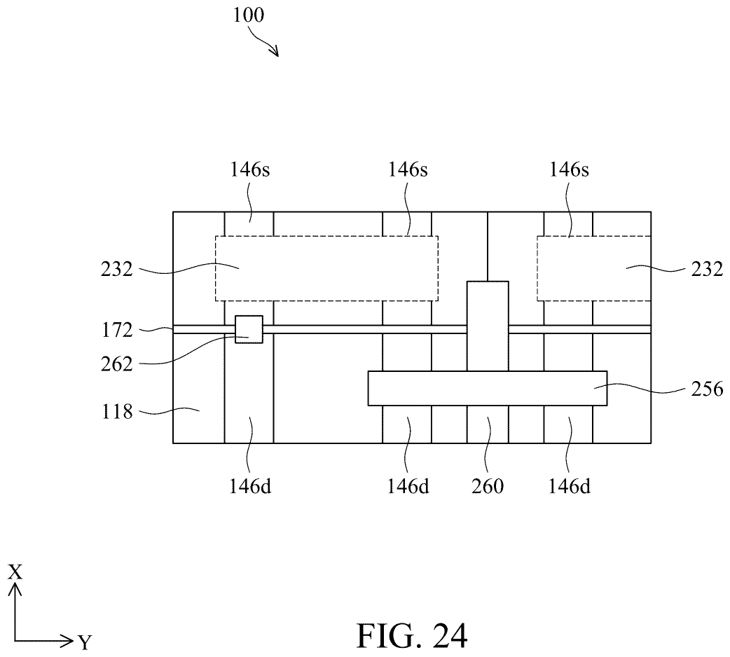

FIGS. 24, 25, 26, and 27 are top views of the semiconductor device structure 100, in accordance with alternative embodiments. In some embodiments, as shown in FIG. 24, the conductive feature 256 is formed on the frontside of the semiconductor device structure 100, and the conductive feature 232 is formed on the backside of the semiconductor device structure 100. Because the backside of the semiconductor device structure 100 is less crowded with the conductive features, the dimensions of the conductive feature 232 may be greater than the dimensions of the conductive feature 256. In some embodiments, the width of the conductive feature 232 along the X direction is greater than the width of the conductive feature 256 along the X direction. With a larger width, the electrical resistance of the conductive feature 232 is reduced.

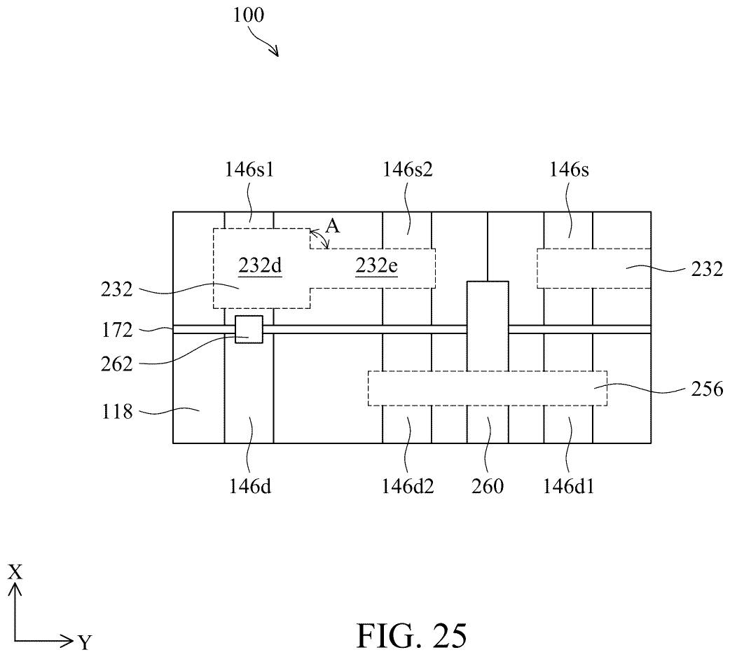

In some embodiments, as shown in FIG. 25, the conductive features 232, 256 are located on the backside of the semiconductor device structure 100. The conductive feature 232 is electrically connected to a first source region 146s1 and a second source region 146s2, and the conductive feature 256 is electrically connected to a first drain region 146d1 and a second drain region 146d2, and the second drain region 146d2 is corresponding to the second source region 146s2. In some embodiments, the portion of the conductive feature 232 electrically connected to the first source region 146s1 has dimensions greater than dimensions of the portion of the conductive feature 232 electrically connected to the second source region 146s2, as shown in FIG. 25. The dimensions of the portion of the conductive feature 232 electrically connected to the second source region 146s2 are reduced in order to reduce parasitic capacitance. In other words, the distance between the portion of the conductive feature 232 electrically connected to the second source region 146s2 and the conductive feature 256 is increased due to the reduced dimensions of the portion of the conductive feature 232, which leads to reduced parasitic capacitance.

In some embodiments, as shown in FIG. 25, the conductive feature 232 includes a first portion 232d located below the source region 146s1 and a second portion 232e located below the source region 146s2. The width of the first portion 232d along the X direction is greater than the width of the second portion 232e along the X direction. In some embodiments, a side of the first portion 232d and a side of the second portion 232e form an angle A, and the angle A may range from about 80 degrees to about 180 degrees. As shown in FIG. 25, in some embodiments, the angle A may be a right angle. The angle A may be determined by the photolithography process to form the opening for the conductive feature 232. In some embodiments, the photolithography process can form an opening that includes two rectangular shaped openings, and the two rectangular shaped openings have different dimensions. The conductive feature 232 deposited in such opening is shown in FIG. 25.

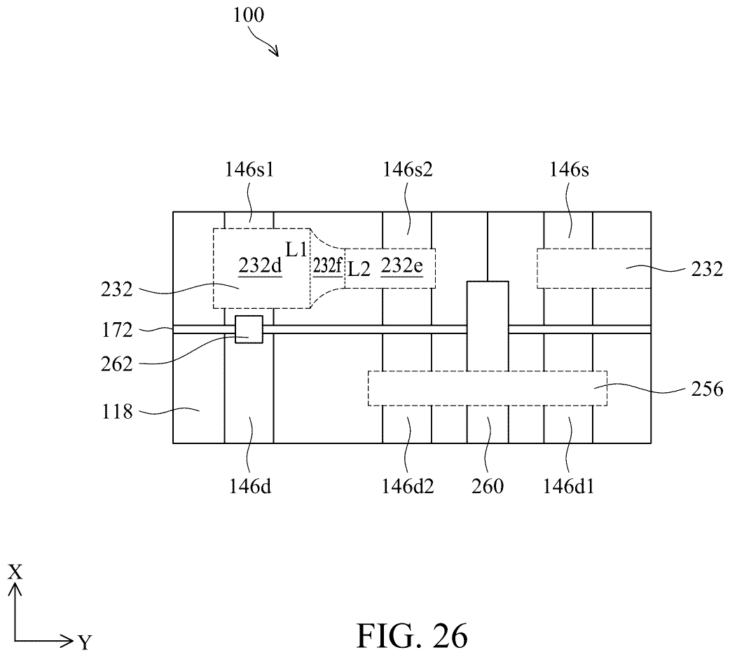

In some embodiments, as shown in FIG. 26, the first and second portions 232d, 232e are connected by connecting portion 232f with a trapezoidal shape. The first, second, and connecting portions 232d, 232e, 232f are monolithic and are defined by imaginary lines L1 and L2. In some embodiments, the connecting portion 232f has curved side surfaces, as shown in FIG. 26. In some embodiments, the connecting portion 232f has planar side surfaces.

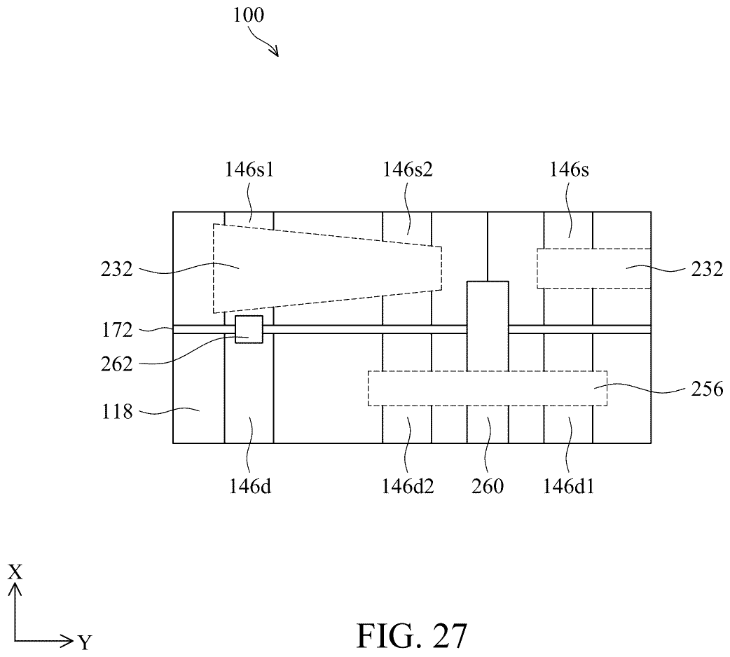

In some embodiments, as shown in FIG. 27, the conductive feature 232 has a trapezoidal shape with the larger end located below the source region 146s1 and the smaller end located below the source region 146s2. With the conductive feature 232 in various embodiments shown in FIGS. 24 to 27, the electrical resistance of the conductive feature 232 is reduced, while the parasitic capacitance is minimized.

Embodiments of the present disclosure provide a semiconductor device structure 100 having a conductive feature 232 located on the backside of the semiconductor device structure 100. In some embodiments, the conductive feature 232 is electrically connected to two S/D regions 146. Some embodiments may achieve advantages. For example, by having the conductive feature 232 located on the backside of the semiconductor device structure 100, the Cgd is reduced.

An embodiment is a semiconductor device structure. The structure includes a first source/drain region including a first epitaxial layer and a second epitaxial layer, and the first epitaxial layer and the second epitaxial layer are doped with a dopant. A concentration of the dopant in the first epitaxial layer is different from a concentration of the dopant in the second epitaxial layer, and a thickness of the first source/drain region is different from a width of the first source/drain region in a cross-sectional view. The structure further includes a second source/drain region disposed adjacent the first source/drain region, a contact etch stop layer disposed over the first source/drain region, and a top surface of the first source/drain region is covered by the contact etch stop layer. The structure further includes a first interlayer dielectric (ILD) layer disposed over the contact etch stop layer, an etch stop layer disposed over a top surface of the contact etch stop layer and a top surface of the first ILD layer, a second ILD layer disposed over the etch stop layer, and a thickness of the first ILD layer is greater than a thickness of the second ILD layer. The structure further includes a first conductive feature disposed below the first and second source/drain regions, and the first conductive feature is electrically connected to the first and second source/drain regions.

Another embodiment is a semiconductor device structure. The structure includes a first source/drain region including a first epitaxial layer and a second epitaxial layer, and the first epitaxial layer and the second epitaxial layer are doped with a dopant. A concentration of the dopant in the first epitaxial layer is different from a concentration of the dopant in the second epitaxial layer, and a thickness of the first source/drain region is different from a width of the first source/drain region in a cross-sectional view. The structure further includes a second source/drain region disposed adjacent the first source/drain region, a contact etch stop layer disposed over the first source/drain region, a first interlayer dielectric (ILD) layer disposed over the contact etch stop layer, an etch stop layer disposed over a top surface of the contact etch stop layer and a top surface of the first ILD layer, a second ILD layer disposed over the etch stop layer, and a thickness of the first ILD layer is greater than a thickness of the second ILD layer. The structure further includes a first conductive feature disposed below the first and second source/drain regions, and the first conductive feature includes a first portion, second portions extending from edges of the first portion, and a third portion extending from a center of the first portion.

A further embodiment is a method. The method includes forming a first source/drain region, the first source/drain region includes a first epitaxial layer and a second epitaxial layer, and the first epitaxial layer and the second epitaxial layer are doped with a dopant. A concentration of the dopant in the first epitaxial layer is different from a concentration of the dopant in the second epitaxial layer, and a thickness of the first source/drain region is different from a width of the first source/drain region in a cross-sectional view. The method further includes forming a second source/drain region adjacent the first source/drain region, depositing a contact etch stop layer over the first and second source/drain regions, depositing a first interlayer dielectric (ILD) layer over the contact etch stop layer, depositing an etch stop layer over the first ILD layer and the contact etch stop layer, depositing a second ILD layer over the etch stop layer, and a thickness of the first ILD layer is greater than a thickness of the second ILD layer. The method further includes flipping over the semiconductor device structure and forming a first conductive feature over the first and second source/drain regions. The first conductive feature includes a first portion, second portions extending from edges of the first portion, and a third portion extending from a center of the first portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first source/drain region comprising a first epitaxial layer and a second epitaxial layer, wherein the first epitaxial layer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view;
a second source/drain region disposed adjacent the first source/drain region;
a contact etch stop layer disposed over the first source/drain region, wherein a top surface of the first source/drain region is covered by the contact etch stop layer;
a first interlayer dielectric (ILD) layer disposed over the contact etch stop layer;
an etch stop layer disposed over a top surface of the contact etch stop layer and a top surface of the first ILD layer;
a second ILD layer disposed over the etch stop layer, wherein a thickness of the first ILD layer is greater than a thickness of the second ILD layer; and
a first conductive feature disposed below the first and second source/drain regions, wherein the first conductive feature is electrically connected to the first and second source/drain regions.

2. The semiconductor device structure of claim 1, wherein the first conductive feature comprises a first portion located below the first source/drain region and a second portion located below the second source/drain region, wherein a width of the first portion is greater than a width of the second portion.

3. The semiconductor device structure of claim 2, wherein a side of the first portion of the first conductive feature and a side of the second portion of the first conductive feature form an angle, and the angle ranges from about 80 degrees to about 180 degrees.

4. The semiconductor device structure of claim 3, wherein the angle is a right angle.

5. The semiconductor device structure of claim 1, wherein the first conductive feature extends through the contact etch stop layer and into the first ILD layer disposed between the first and second source/drain regions.

6. The semiconductor device structure of claim 1, further comprising a second conductive feature electrically connected with the second source/drain region.

7. The semiconductor device structure of claim 6, wherein the second conductive feature is disposed over the second source/drain region and is extending through the first ILD layer and the contact etch stop layer.

8. The semiconductor device structure of claim 6, wherein the second conductive feature is disposed below the second source/drain region.

9. The semiconductor device structure of claim 8, further comprising an air gap surrounding the second conductive feature.

10. A semiconductor device structure, comprising:
a first source/drain region comprising a first epitaxial layer and a second epitaxial layer, wherein the first epitaxial layer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view;
a second source/drain region disposed adjacent the first source/drain region;
a contact etch stop layer disposed over the first source/drain region;
a first interlayer dielectric (ILD) layer disposed over the contact etch stop layer;
an etch stop layer disposed over a top surface of the contact etch stop layer and a top surface of the first ILD layer;
a second ILD layer disposed over the etch stop layer, wherein a thickness of the first ILD layer is greater than a thickness of the second ILD layer; and
a first conductive feature disposed below the first and second source/drain regions, wherein the first conductive feature comprises a first portion, second portions extending from edges of the first portion, and a third portion extending from a center of the first portion.

11. The semiconductor device structure of claim 10, wherein the first portion, second portion, and third portion are monolithic.

12. The semiconductor device structure of claim 10, wherein the first portion has a first height, the second portion has a second height different from the first height, and the third portion has a third height different from the second height.

13. The semiconductor device structure of claim 12, wherein the first height is greater than the second height, and the second height is greater than the third height.

14. The semiconductor device structure of claim 12, wherein the second height is greater than the first height, and the first height is greater than the third height.

15. The semiconductor device structure of claim 10, further comprising a gate electrode layer, a third source/drain region, a fourth source/drain region, and a fifth source/drain region, wherein the second and fourth source/drain regions are disposed on opposite sides of the gate electrode layer, and the third and fifth source/drain regions are disposed on opposite sides of the gate electrode layer.

16. The semiconductor device structure of claim 15, further comprising a second conductive feature electrically connected with the fourth and fifth source/drain regions.

17. A method for forming a semiconductor device structure, comprising:
forming a first source/drain region, wherein the first source/drain region comprises a first epitaxial layer and a second epitaxial layer, wherein the first epitaxial layer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view;
forming a second source/drain region adjacent the first source/drain region;
depositing a contact etch stop layer over the first and second source/drain regions;
depositing a first interlayer dielectric (ILD) layer over the contact etch stop layer;
depositing an etch stop layer over the first ILD layer and the contact etch stop layer;
depositing a second ILD layer over the etch stop layer, wherein a thickness of the first ILD layer is greater than a thickness of the second ILD layer;
flipping over the semiconductor device structure; and
forming a first conductive feature over the first and second source/drain regions, wherein the first conductive feature comprises a first portion, second portions extending from edges of the first portion, and a third portion extending from a center of the first portion.

18. The method of claim 17, wherein the forming of the first conductive feature comprises:
thinning a substrate to expose an insulating material;
depositing a hardmask layer over the insulating material; and
forming an opening in the hardmask layer and the insulating material.

19. The method of claim 18, wherein the forming of the opening comprises removing a first substrate portion disposed over the first source/drain region and removing a second substrate portion disposed over the second source/drain region.

20. The method of claim 19, wherein the forming of the opening further comprises removing a first semiconductor layer and a first dielectric layer disposed over the first source/drain region and removing a second semiconductor layer and a second dielectric layer disposed over the second source/drain region.
